(19) United States
(12) Patent Application Publication
(10) Pub. No.: US 2007/0210368 A1
(43) Pub. Date: Sep. 13, 2007

(54) GATE STRUCTURE AND METHOD OF FORMING THE GATE STRUCTURE, SEMICONDUCTOR DEVICE HAVING THE GATE STRUCTURE AND METHOD OF MANUFACTURING THE SEMICONDUCTOR DEVICE

(75) Inventors: Eun-Suk CHO, Gyeonggi-do (KR); Jong-Jin LEE, Gyeonggi-do (KR); Dong-Gun PARK, Gyeonggi-do (KR); Jeong-Dong CHOE, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/683,364

(22) Filed: Mar. 7, 2007

(30) Foreign Application Priority Data
Mar. 8, 2006 (KR) 2006-0021580

(51) Int. Cl. H01L 21/3205; H01L 29/76

(52) U.S. Cl. 257/314; 438/585

(57) ABSTRACT

A gate structure in a semiconductor device includes a tunnel insulation layer disposed on a substrate, a first charge trapping layer disposed on the tunnel insulation layer, a second charge trapping layer disposed on the first charge trapping layer, a dielectric layer disposed to cover the second charge trapping layer, and a conductive layer pattern disposed on the dielectric layer. The first charge trapping layer includes charge trapping sites for storing charges therein. The second charge trapping layer includes nanocrystals. The semiconductor device including the gate structure may have a sufficiently wide programming/erasing window and an improved data retention capability.

### CROSS-REFERENCE TO RELATED APPLICATIONS

This application claims priority under 35 USC § 119 to Korean Patent Application No. 2006-21580 filed on Mar. 8, 2006, the contents of which are herein incorporated by reference in their entirety.

### BACKGROUND

1. Technical Field

Example embodiments of the present invention relate to a gate structure, a method of forming the gate structure, a semiconductor device having the gate structure, and a method of manufacturing the semiconductor device. More particularly, example embodiments of the present invention relate to a gate structure including a nanocrystalline structure as a charge trapping layer for storing charges, a method of forming the gate structure, a semiconductor device having the gate structure, and a method of manufacturing the semiconductor device.

2. Description of the Related Art

Generally, a memory cell of a non-volatile memory device has a stacked gate structure that includes a tunnel oxide layer, a floating gate and a control gate. Charges are usually injected into the floating gate and emitted from the floating gate. The floating gate may generally include polysilicon.

The non-volatile memory cell having the stacked gate structure may be programmed by injecting hot electrons, which are generated in a channel region thereof, into the floating gate after overcoming an energy barrier of the tunnel oxide layer. On the other hand, data stored in the non-volatile memory cell may be erased by removing the electrons, which are emitted from the floating gate in accordance with Fowler-Nordheim (F-N) tunneling between the floating gate and a source region. Specifically, when a high voltage is applied to the control gate so as to cause an electric potential difference between the source region and a drain region, the hot electrons generated in the channel region near the drain region may be injected into the floating gate by overcoming the energy barrier of the tunnel oxide layer. On the other hand, when a high voltage is applied to the source region and voltages of 0V are applied to the control gate and a substrate, F-N tunneling may be caused between the source region and the floating gate so that the electrons stored in the floating gate may be emitted. It is important that once a cell has been programmed, by injecting the electrons, the electrons remain in the floating gate and do not leak out to other areas of the memory cell. If too many electrons are able to leak out of the floating gate, the reliability of the memory cell will be compromised.

Although the floating gate including polysilicon has a good charge storing capability, a difference between threshold voltages of programming and erasing operations of the non-volatile semiconductor device may be considerably large.

FIG. 1 is a graph showing a programming/erasing window of a conventional non-volatile memory device.

The programming/erasing window of the conventional non-volatile memory device indicates the difference between the threshold voltages in the programming and the erasing operations of the non-volatile memory device. When the programming/erasing window is wide, the difference between the threshold voltages of the programming and the erasing operations may be large so that data stored in memory cell of the non-volatile memory device may be easily identified in a reading operation of the non-volatile memory device. In other words, since the threshold voltage difference between a programmed cell and an erased cell is large, reading the data in the memory cell is relatively easy.

Since charges are stored in the floating gate as free electrons, the charges stored in the floating gate may be emitted when defects are generated in the tunnel oxide layer formed beneath the floating gate. In other words, electrons may leak through the tunnel oxide layer into the channel region of the memory cell. Further, the tunnel oxide layer, through which the charges pass, has a high energy barrier. This could be seen in an energy band diagram of the non-volatile memory cell having the stacked gate structure. Therefore, a tunneling probability of the charges may be excessively reduced when the tunnel oxide layer is relatively thick. Hence, it is desirable that the tunnel oxide layer have a thin and uniform thickness. However, the tunnel oxide layer being both uniform and thin may not be easily formed on a substrate by the conventionally used manufacturing technologies. As a result, the non-volatile memory device may have considerable lost charges because of the defects of the tunnel oxide layer.

To overcome the above-mentioned problem, a non-volatile memory device including nanocrystals for storing charges instead of the floating gate including polysilicon has been proposed.

In the non-volatile memory device including the nanocrystals as a charge trapping layer, charges may be dispersed and trapped into a plurality of nanocrystals so that the charges may be sufficiently stored in other nanocrystals even though some nanocrystals may have defects. In other words, electrons may leak out of some defective nanocrystals, but electrons will be retained in the other nanocrystals. Thus, a leakage current from the nanocrystals may be reduced in comparison with the non-volatile memory device having the floating gate of polysilicon. Additionally, the non-volatile memory device including the nanocrystals may have an enhanced data retention capability. For example, U.S. Pat. No. 6,444,545 (issued to Michael Sadd, et al.) discloses a method of manufacturing a non-volatile memory device having a transformed SONOS type that includes nanocrystals using a silicon-rich silicon nitride layer.

In the above-mentioned non-volatile memory device including the nanocrystals, charge trapping sites of the non-volatile memory device may not be sufficiently ensured because desired nanocrystals may not be formed in a limited area of the non-volatile memory device. Hence, it is not easy to discriminate data stored in a memory cell of the non-volatile memory device because a difference between a threshold voltage after an erasing operation and a threshold voltage after a programming operation may be considerably small. As a result, an operation failure of the non-volatile memory device may frequently occur.

When the non-volatile memory device includes metal nanocrystals as the charge trapping layer, the threshold voltage difference can be increased, but metal may be easily diffused to an underlying layer, such as a tunnel oxide layer, such that the tunnel oxide layer may be contaminated by the metal. Thus, a reliability of the non-volatile memory device may be greatly reduced. The invention addresses these and other disadvantages of the conventional art.

### SUMMARY

Example embodiments of the present invention provide a gate structure, and a method of forming the gate structure, having an excellent data retention capability and an improved reliability by reducing contamination of a tunnel insulation layer caused by metal diffusion.

Example embodiments of the present invention also provide a semiconductor device, and a method of manufacturing the semiconductor device, that has a sufficiently wide threshold voltage window in a programming operation and an erasing operation, and an improved reliability by reducing a contamination of a tunnel insulation layer caused by metal diffusion.

### BRIEF DESCRIPTION OF THE DRAWINGS

The above and other features and advantages of the present invention will become more apparent by describing in detail example embodiments thereof with reference to the accompanying figures, in which:

FIG. 1 is a graph showing a programming/erasing window of a conventional non-volatile memory device;

FIG. 2 is a cross-sectional view illustrating a gate structure in accordance with example embodiments of the present invention;

FIGS. 3 to 6 are cross-sectional views illustrating a method of forming a gate structure in accordance with example embodiments of the present invention;

FIG. 7 is a cross-sectional view illustrating a semiconductor device in accordance with example embodiments of the present invention; and

FIGS. 8 to 12 are cross-sectional views illustrating a method of manufacturing a semiconductor device in accordance with example embodiments of the present invention.

### DETAILED DESCRIPTION

The present invention is described more fully hereinafter with reference to the accompanying figures, in which example embodiments of the present invention are shown. The invention may, however, be embodied in many different forms and should not be construed as limited to the embodiments set forth herein. Rather, these embodiments are provided so that this disclosure will be thorough and complete, and will fully convey the scope of the present invention to those skilled in the art. In the figures, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “beneath,” “below,” “lower,” “above,” “upper” and the like, may be used herein for ease of description to describe one element or feature's relationship to another element or features as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented or rotated 90 degrees or at other orientations and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments and intermediate structures of the invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted regions. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms including technical and scientific terms used herein have the same meaning as commonly understood by one of ordinary skill in the art to which the invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

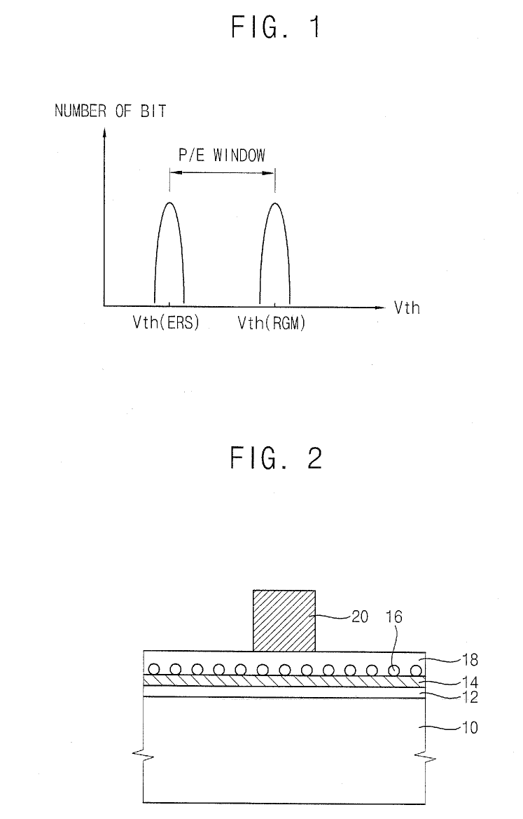

FIG. 2 is a cross-sectional view illustrating a gate structure in accordance with example embodiments of the present invention.

Referring to FIG. 2, a tunnel insulation layer 12 is formed on a substrate 10. The substrate 10 may include single crystalline silicon. The tunnel insulation layer 12 may include an oxide such as silicon oxide or an oxynitride such as silicon oxynitride. The tunnel insulation layer 12 may be formed by a thermal oxidation process or a chemical vapor deposition (CVD) process. For example, the tunnel insulation layer 12 may have a thickness of about 10 Å to about 50 Å.

A first charge trapping layer 14 is formed on the tunnel insulation layer 12. The first charge trapping layer 14 may include a material having charge trapping sites therein. Thus, charges may be stored in the first charge trapping layer 14. Additionally, the first charge trapping layer 14 may prevent the diffusion of metal. The first charge trapping layer 14 may be formed using a nitride. For example, the first charge trapping layer 14 may be formed using silicon nitride.

A silicon nitride layer may include a plurality of charge trapping sites therein so that charges may be stored in the charge trapping sites or may be emitted from the charge trapping sites. Since the charges may be stored in deep energy levels in the charge trapping sites, the stored charges may not easily leak out from the charge trapping sites. Thus, the first charge trapping layer 14 may have an excellent data retention capability when the first charge trapping layer 14 includes silicon nitride. Further, the first charge trapping layer 14, including silicon nitride, may serve as a barrier layer for preventing metal, which is included in a layer successively formed, from diffusing into the tunnel insulation layer 12. Preventing metal from diffusing into the tunnel insulation layer 12 will improve the reliability and data retention capability of the gate structure.

When the first charge trapping layer 14 has a thickness below about 10 Å, the first charge trapping layer 14 may not properly serve as both a charge trapping layer and a barrier layer. When the first charge trapping layer 14 has a thickness above about 50 Å, the first charge trapping layer 14 may have defects caused by a stress generated therein. Thus, the first charge trapping layer 14 preferably has a thickness of about 10 Å to about 50 Å. In an example embodiment, the first charge trapping layer 14 may have a thickness of about 30 Å.

A second charge trapping layer 16 is formed on the first charge trapping layer 14. The second charge trapping layer 16 may include nanocrystals. In one example embodiment, the second charge trapping layer 16 may include a nanocrystalline metal nitride. In another example embodiment, the second charge trapping layer 16 may include a nanocrystalline silicon compound. In other words, the second charge trapping layer 16 may include metal nanocrystals or silicon nanocrystals.

When the second charge trapping layer 16 includes metal nanocrystals, the first charge trapping layer 14 may serve as a charge trapping layer and a barrier layer for preventing the diffusion of metal from the second charge trapping layer 16.

In one example embodiment, the second charge trapping layer 16 may include nanocrystalline tungsten nitride. In another example embodiment, the second charge trapping layer 16 may include nanocrystalline silicon oxide, nanocrystalline silicon nitride, nanocrystalline silicon oxynitride, etc. In example embodiments, nanocrystalline silicon oxide, nanocrystalline silicon nitride and nanocrystalline silicon oxynitride may correspond to silicon-rich oxide, silicon-rich nitride and silicon-rich oxynitride, respectively.

The nanocrystals in the second charge trapping layer 16 may store charges and may emit the stored charges. That is, the charges may be separately injected into the nanocrystals of the second charge trapping layer 16 while programming a semiconductor device. Since the nanocrystals are separated from one another in the second charge trapping layer 16, the injected charges may not move in the second charge trapping layer 16. Hence, the charges trapped in the nanocrystals may not leak out from the second charge trapping layer 16 even though a leakage current caused by defects in the tunnel insulation layer 12 is generated from the tunnel insulation layer 12. As a result, the data retention capability of the semiconductor device may be considerably improved.

Since the first and the second charge trapping layers 14 and 16 independently store the charges, a lot of charges may be stored in the first and the second charge trapping layers 14 and 16. Thus, the difference between a threshold voltage of a programming operation and a threshold voltage of an erasing operation may be greatly increased. As a result, a failure of a cell transistor in the semiconductor device may be considerably reduced by increasing the programming/erasing window of the semiconductor device.

A dielectric layer 18 is disposed on the second charge trapping layer 16. The dielectric layer 18 may include an oxide such as silicon oxide. Alternatively, the dielectric layer 18 may include a metal oxide having a high dielectric constant.

After the programming operation or the erasing operation of the semiconductor device is carried out, the dielectric layer 18 may prevent the charges that are stored in the first and the second charge trapping layers 14 and 16 from being emitted toward a conductive layer pattern 20 serving as an electrode. Additionally, the dielectric layer 18 may prevent charges in the conductive layer pattern 20 from being injected into the first charge trapping layer 14 and/or the second charge trapping layer 16. Furthermore, the dielectric layer 18 may ensure that most of the voltage applied to the electrode is dropped across the tunnel insulation layer 12 while performing the programming and the erasing operations. To ensure the above-mentioned characteristics of the dielectric layer 18, the dielectric layer 18 may include the metal oxide because the metal oxide has a dielectric constant substantially higher than that of silicon oxide. Examples of the metal oxide for the dielectric layer 18 may include aluminum oxide, zirconium oxide, zirconium silicon oxide, hafnium oxide, hafnium silicon oxide, titanium oxide, tantalum oxide, etc. These may be used alone or in a mixture thereof. In example embodiments, the dielectric layer 18 may have a single layer structure of metal oxide or a multilayer structure of different metal oxides.

When the dielectric layer 18 includes silicon oxide, the dielectric layer 18 may be contaminated because of upwardly diffusing metal in the second charge trapping layer 16 that includes the metal nanocrystals. When the dielectric layer 18 includes the metal oxide, however, the metal oxide may effectively prevent the diffusion of the metal in the second charge trapping layer 16. Hence, the dielectric layer 18 may advantageously include the metal oxide when the second charge trapping layer 16 includes the metal nanocrystals.

The conductive layer pattern 20 serving as the electrode is formed on the dielectric layer 18. The conductive layer pattern 20 may include polysilicon, a metal nitride or a metal having a work function above about 4.0 eV. Examples of the metal for the conductive layer pattern 20 may include titanium, titanium nitride, tantalum, tantalum nitride, etc. Alternatively, the conductive layer pattern 20 may include a mixture of polysilicon, metal and/or metal nitride.

When the dielectric layer 18 includes the metal oxide, the conductive layer pattern 20 may advantageously include a metal having a work function above about 4.5 eV because the conductive layer pattern 20 including polysilicon may cause a Fermi level pinning phenomenon in which the Fermi level of the conductive layer pattern 20 is fixed to a constant value. Hence, the conductive layer pattern 20 may not have a desired high work function above about 4.5 eV so that the charges may be reversely tunneled from the conductive layer pattern 20 toward the first charge trapping layer 14 and/or the second charge trapping layer 16 in the erasing operation of the semiconductor device. In other words, when the dielectric layer 18 includes the metal oxide, a conductive layer pattern 20 including polysilicon may not provide a high enough energy barrier to prevent reverse tunneling of charges into the first and second charge trapping layers 14 and 16 during an erase operation. In this case, the erase operation may not be completely successful and the data stored in the memory cell may become indeterminate. As an example, reverse tunneling of charges may decrease the difference between the threshold voltages associated with programming and erasing operations.

When the dielectric layer 18 includes the metal oxide and the conductive layer pattern 20 includes the metal having the work function above about 4.5 eV, driving voltages of the programming and the erasing operations may be reduced and also a response speed of the semiconductor device may be improved. Further, the diffusion of the metal in the second charge trapping layer 16 may be effectively prevented.

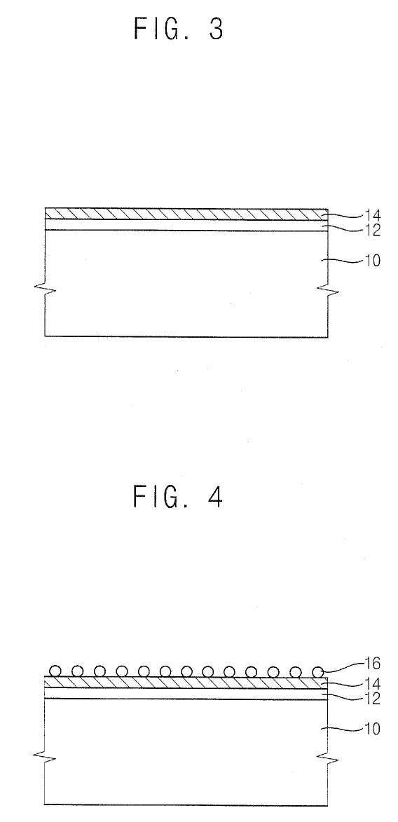

FIGS. 3 to 6 are cross-sectional views illustrating a method of a gate structure in accordance with example embodiments of the invention.

Referring to FIG. 3, a tunnel insulation layer 12 is formed on a substrate 10 including single crystalline silicon. The tunnel insulation layer 12 may have a thickness of about 10 Å to about 50 Å. The tunnel insulation layer 12 may be formed using silicon oxide or silicon oxynitride. Additionally, the tunnel insulation layer 12 may be formed by a thermal oxidation process or a CVD process.

A first charge trapping layer 14 is formed on the tunnel insulation layer 12. The first charge trapping layer 14 may be formed using a material that has charge trapping sites and prevents a diffusion of metal. For example, the first charge trapping layer 14 may be formed using a nitride. In an example embodiment, the first charge trapping layer 14 may be formed using silicon nitride. The first charge trapping layer may have a thickness of about 30 Å.

Referring to FIG. 4, a second charge trapping layer 16 including nanocrystals is formed on the first charge trapping layer 14.

In one example embodiment of the present invention, the second charge trapping layer 16 may include metal nanocrystals. Here, the second charge trapping layer 16 may be formed using a metal nitride such as tungsten nitride. When the second charge trapping layer 16 includes the metal nanocrystals, the second charge trapping layer 16 may be formed by a low pressure chemical vapor deposition (LPCVD) process or an ultra-high vacuum chemical vapor deposition (UHCVD) process. The second charge trapping layer 16 may be completed by a heat treatment process. Here, sizes and densities of the metal nanocrystals in the second charge trapping layer 16 may be controlled by adjusting processing conditions of the deposition process and the heat treatment process.

Normally, in the above-described processes of forming the metal nanocrystals, metal in the second charge trapping layer 16 may be easily diffused into the tunnel insulation layer 12. However, according to the present invention, the first charge trapping layer 14 including nitride is formed beneath the second charge trapping layer 16 so that the diffusion of metal in the second charge trapping layer 16 may be prevented by the first charge trapping layer 14.

In other example embodiments of the present invention, the second charge trapping layer 16 may include silicon nanocrystals. Here, the second charge trapping layer 16 may be formed of a silicon-rich oxide layer, a silicon-rich nitride layer or a silicon-rich oxynitride layer. When one of the silicon-rich oxide layer, the silicon-rich nitride layer and the silicon-rich oxynitride layer is thermally treated, excess silicon atoms, which are not combined with oxygen, may cohere with one another so that the second charge trapping layer 16 including the silicon nanocrystals is completed on the first charge trapping layer 14.

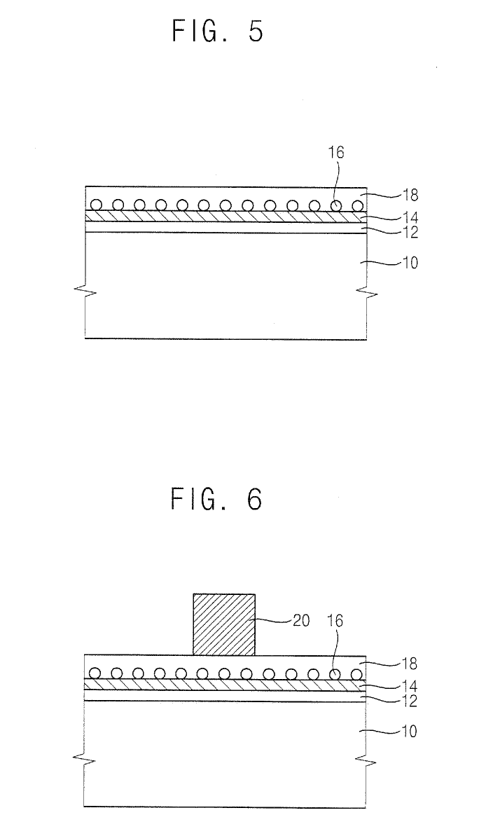

Referring to FIG. 5, a dielectric layer 18 is formed on the second charge trapping layer 16. In one example embodiment, the dielectric layer 18 may be formed using an oxide such as silicon oxide. In another example embodiment, the dielectric layer 18 may be formed using a metal oxide that has a high dielectric constant such as aluminum oxide, zirconium oxide, zirconium silicon oxide, hafnium oxide, hafnium silicon oxide, titanium oxide, tantalum oxide, etc. These may be used alone or in a mixture thereof. The dielectric layer 18 may have a single layer structure or a multi-layered structure. The dielectric layer 18 may be formed by a chemical vapor deposition (CVD) process or an atomic layer deposition (ALD) process.

When the dielectric layer 18 includes the metal oxide, the dielectric layer 18 may additionally serve as a barrier layer for preventing the diffusion of the metal in the second charge trapping layer 16. That is, the dielectric layer 18 may be advantageously formed using the metal oxide so as to prevent the diffusion of the metal from the second charge trapping layer 16 that includes the metal nanocrystals.

Referring to FIG. 6, a conductive layer (not shown) is formed on the dielectric layer 18. The conductive layer may be formed using polysilicon or a metal or a metal nitride having a work function above about 4.0 eV. The conductive layer may have a single layer structure or a multi-layered structure. Examples of the metal or the metal nitride in the conductive layer may include titanium, titanium nitride, tantalum, tantalum nitride, etc. When the dielectric layer 18 includes the metal oxide, the conductive layer may be advantageously formed using a metal having a work function above about 4.5 eV.

The conductive layer is patterned by a photolithography process to form a conductive layer pattern 20 on the dielectric layer 18. Thus, a gate structure is formed on the substrate 10. The gate structure may include the tunnel insulation layer pattern 12, the first charge trapping layer 14, the second charge trapping layer 16, the dielectric layer 18 and the conductive layer pattern 20. The conductive layer pattern 20 may serve as an electrode.

When the dielectric layer 18 is formed using the metal oxide, the dielectric layer 18 may not be easily etched by a dry etching process or a wet etching process. In some example embodiments, the dielectric layer 18, the second charge trapping layer 16 and the first charge trapping layer 14 may not be etched. Although the dielectric layer 18, the second charge trapping layer 16 and the first charge trapping layer 14 are not patterned, a semiconductor device having the resultant structure may ensure a proper operation because charges may only be stored in the first and second charge trapping layers 14 and 16 positioned under the conductive layer pattern 20.

When the dielectric layer 18 includes silicon oxide, the dielectric layer 18, the second charge trapping layer 16 and the first charge trapping layer 14 may be sequentially patterned to complete the gate structure on the substrate 10.

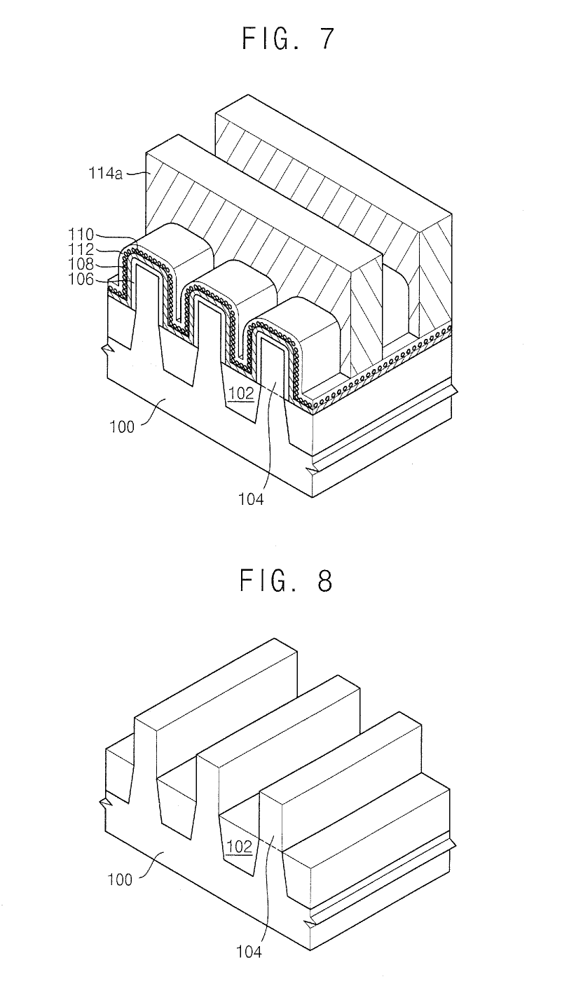

FIG. 7 is a cross-sectional view illustrating a semiconductor device in accordance with example embodiments of the invention. Although FIG. 7 illustrates a NAND type non-volatile semiconductor device, the features of the invention may be advantageously employed for another non-volatile semiconductor device or a volatile semiconductor device such as a DRAM device or an SRAM device.

Referring to FIG. 7, a substrate 100 is divided into an active region 104 and a field region 102. The active region 104 may have a pin shape protruding from the substrate 100 so that the active region 104 may be referred to as an active pin. The active region 104 may extend along a first direction.

A tunnel insulation layer 106 is provided on the active region 104 of the substrate 100. The tunnel insulation layer 106 may include silicon oxide or silicon oxynitride. The tunnel insulation layer 106 may be formed by a thermal oxidation process or a CVD process. The tunnel insulation layer 106 may have a thickness of about 10 Å to about 50 Å measured from an upper face of the active region 104. The tunnel insulation layer 106 may have an effective area substantially larger than that of a conventional tunnel insulation layer because the tunnel insulation layer 106 is formed on an upper face and lateral faces of the active region 104 protruded from the substrate 100.

A first charge trapping layer 108 is formed on the tunnel insulation layer 106. The first charge trapping layer 108 may include a material having charge trapping sites for storing charges therein. In addition, the first charge trapping layer 108 may prevent metal that is deposited in a second charge trapping layer 110 from diffusing into the tunnel insulation layer 106. The first charge trapping layer 108 may include a nitride. For example, the first charge trapping layer 108 may include silicon nitride.

When the first charge trapping layer 108 has a thickness less than about 10 Å, the first charge trapping layer 108 may not properly serve as a charge trapping layer for storing the charges and as a barrier layer for preventing the diffusion of metal. When the first charge trapping layer 108 has a thickness greater than 50 Å, the first charge trapping layer 108 may be damaged by a stress generated while forming the first charge trapping layer 108. Thus, the first charge trapping layer 108 preferably has a thickness of about 10 Å to about 50 Å based on an upper face of the tunnel insulation layer 106. For example, the first charge trapping layer 108 may have a thickness of about 30 Å.

Since the first charge trapping layer 108 is formed over the upper face and lateral faces of the active region 104, the first charge trapping layer 108 may also have an effective area substantially larger than that of a conventional charge trapping layer having a flat structure. Thus, effective charge trapping sites in the first charge trapping layer 108 may be increased because of an increase in the effective area between the tunnel insulation layer 106 and the first charge trapping layer 108.

A second charge trapping layer 110 including nanocrystals is formed on the first charge trapping layer 108. The second charge trapping layer 10 may include nanocrystals of metal or nanocrystals of silicon. The second charge trapping layer 110 may also have an enlarged effective area because the second charge trapping layer 110 is formed over the upper face and the lateral faces of the first charge trapping layer 108.

When the second charge trapping layer 110 includes the metal nanocrystals, the first charge trapping layer 108 may serve as the charge trapping layer and the barrier layer for preventing the metal from being diffused from the second charge trapping layer 110. In one example embodiment, the second charge trapping layer 110 may be formed using a metal nitride such as tungsten nitride. In another example embodiment, the second charge trapping layer 10 may be formed using a silicon compound such as silicon-rich oxide, silicon-rich nitride or silicon-rich oxynitride.

In general, a nano-sized dot may have a size of about 30 Å to about 50 Å in diameter so that the number of nanocrystals positioned in one nano-sized dot may be limited. When a non-volatile semiconductor device has a minute design rule, the number of the nanocrystals formed in a charge trapping layer may be considerably reduced. However, according to some embodiments of the invention, the nanocrystals may be formed in the second charge trapping layer 110 having the enlarged effective area. Thus, the number of the nanocrystals in the second charge trapping layer 110 may be increased and also the number of the charges trapped in the second charge trapping layer 110 may be correspondingly increased.

As described above, the effective areas of the first and the second charge trapping layers 108 and 110 are increased such that an increased number of charges may be trapped in the first and the second charge trapping layers 108 and 110. Therefore, a difference between a threshold voltage in a programming operation and a threshold voltage in an erasing operation may be greatly increased. As a result, a programming/erasing window of the semiconductor device may be increased to reduce operation failures of the semiconductor device.

A dielectric layer 112 is formed on the second charge trapping layer 110. The dielectric layer 112 may include an oxide such as silicon oxide or a metal oxide having a high dielectric constant. The metal oxide for the dielectric layer 112 may include aluminum oxide, zirconium oxide, zirconium silicon oxide, hafnium oxide, hafnium silicon oxide, etc. These may be used alone or in a mixture thereof. The dielectric layer 112 may have a single layer structure or a multi-layered structure.

A conductive layer pattern 114a is formed on the dielectric layer 112. The conductive layer pattern 114a may extend along a second direction substantially perpendicular to the first direction. In some example embodiments, the conductive layer pattern 114a may have a line shape. The conductive layer pattern 110a may include polysilicon, a metal nitride or a metal having a work function above about 4.0 eV. These may be used alone or in a mixture thereof. For example, the conductive layer pattern 114a may include titanium, titanium nitride, tantalum, tantalum nitride, etc. When the dielectric layer 112 includes the metal oxide, the conductive layer pattern 114a may include a metal having a work function above about 4.5 eV.

Impurity regions (not shown) are formed at portions of the active region 104 adjacent to the conductive layer pattern 114a. The impurity regions may be formed by an ion implantation process and a heat treatment process.

FIGS. 8 to 12 are cross-sectional views illustrating a method of manufacturing a semiconductor device in accordance with example embodiments of the invention. Although FIGS. 8 to 12 illustrate a NAND type non-volatile semiconductor device, the features of the invention may be advantageously employed for another non-volatile semiconductor device or a volatile semiconductor device such as a DRAM device or an SRAM device.

Referring to FIG. 8, an active region 104 and a field region 102 are defined on a substrate 100. The active region 104 may have an active pin structure and extend along a first direction. The active region 104 and the field region 102 may be defined in accordance with the formation of an isolation layer.

In some example embodiments of the invention, a preliminary active region may be formed by partially etching the substrate 100 including single crystalline silicon along the first direction. A preliminary isolation layer may be formed on a portion of the substrate 100 adjacent to the preliminary active region. The preliminary isolation layer may be formed using an oxide such as silicon oxide. Then, the preliminary isolation layer may be partially etched so that the isolation region 102 may be formed on the substrate 100 and the active region 104 having the active pin structure may be simultaneously formed on the substrate 100.

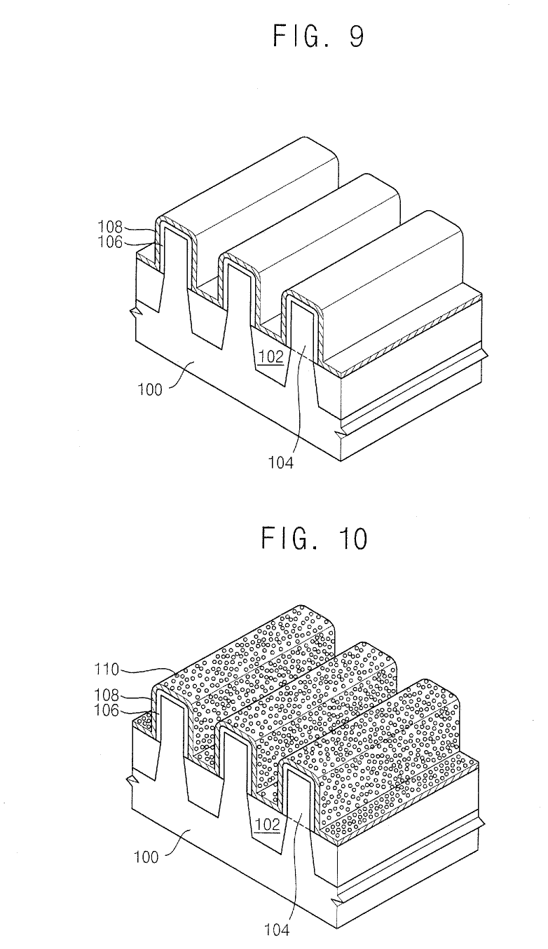

Referring to FIG. 9, a tunnel insulation layer 106 is formed on the active region 104. The tunnel insulation layer 106 may be formed using silicon oxide or silicon oxynitride. For example, the tunnel oxide layer 106 may have a thickness of about 10 Å to about 50 Å measured from an upper face of the active region 104. When the tunnel insulation layer 106 includes silicon oxide, the tunnel insulation layer 106 may be formed by a thermal oxidation process.

A first charge trapping layer 108 is formed on the tunnel insulation layer 106. The first charge trapping layer 108 may be formed using a material that includes charge trapping sites. Additionally, the material in the first charge trapping layer 108 may prevent diffusion of metal from a second charge trapping layer 110 that is subsequently formed. For example, the first charge trapping layer 108 may be formed using a nitride such as silicon nitride.

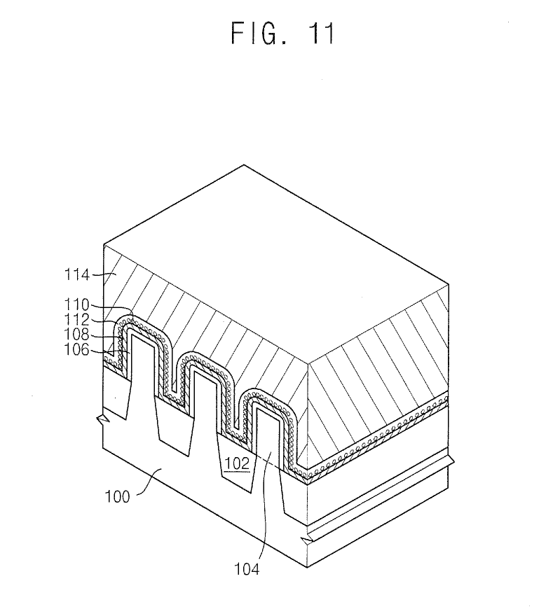

Referring to FIG. 10, the second charge trapping layer 110 including nanocrystals is formed on the first charge trapping layer 108.

In one example embodiment of the invention, the second charge trapping layer 110 may include nanocrystals of metal. The second charge trapping layer 110 may be formed using a metal nitride such as tungsten nitride. In the formation of the second charge trapping layer 110 having the nanocrystals of metal, the metal in the second charge trapping layer 110 may be easily diffused into the tunnel insulation layer 106. Since the first charge trapping layer 108 including nitride is formed beneath the second charge trapping layer 110, the diffusion of the metal from the second charge trapping layer 110 may be effectively prevented.

In another example embodiment of the invention, the second charge trapping layer 110 may include nanocrystals of silicon. The second charge trapping layer 110 may be formed using silicon-rich oxide, silicon-rich nitride or silicon-rich oxynitride.

The first and the second charge trapping layers 108 and 110 may have enlarged dimensions because the first and the second charge trapping layers 108 and 110 are formed over the active region 104 having the protruding pin structure. That is, effective areas of the first and the second charge trapping layers 108 and 110 may be considerably increased such that a relatively high number of charges may be trapped in the first and the second charge trapping layers 108 and 110. Accordingly, a difference between a threshold voltage in a programming operation and a threshold voltage in an erasing operation may be increased while operating the semiconductor device. As a result, a programming/erasing window of the semiconductor device may be improved to thereby reduce operation failures of the semiconductor device.

Referring to FIG. 11, a dielectric layer 112 is formed on the second charge trapping layer 110. The dielectric layer 112 may be formed using an oxide or a metal oxide having a high dielectric constant. For example, the dielectric layer 112 may be formed using silicon oxide, aluminum oxide, zirconium oxide, zirconium silicon oxide, hafnium oxide, hafnium silicon oxide, etc. These may be used alone or in a mixture thereof. The dielectric layer 112 may have a single layer structure or a multi-layered structure.

When the dielectric layer 112 is formed using the metal oxide, the dielectric layer may serve as a barrier layer for preventing the diffusion of the metal from the second charge trapping layer 110.

A conductive layer 114 is formed on the dielectric layer 112. The conductive layer 114 may be formed using polysilicon, a metal or a metal nitride. The metal included in the conductive layer 114 may have a work function above about 4.0 eV. Examples of the metal or the metal nitride for the conductive layer 114 may include titanium, titanium nitride, tantalum, tantalum nitride, etc. These may be used alone or in a mixture thereof. The conductive layer 114 may have a single layer structure or a multi-layered structure.

When the dielectric layer 112 is formed using the metal oxide, the conductive layer 114 may be advantageously formed to have the multi-layered structure that includes a metal film having a work function above about 4.5 eV and a polysilicon film formed on the metal film.

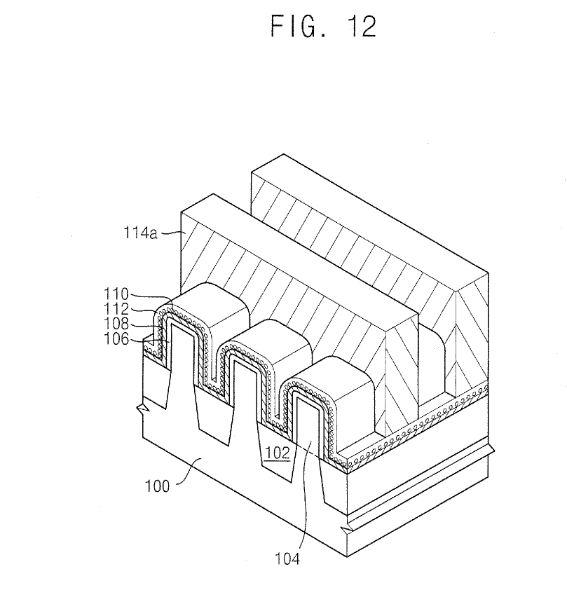

Referring to FIG. 12, a conductive layer pattern 114a serving as an electrode is formed on the dielectric layer 112 by partially etching the conductive layer 1114. Then, impurities may be implanted into portions of the active region 104 adjacent to the conductive layer pattern 114a so that impurity regions (not shown) may be formed in the active region 104.

According to example embodiments of the invention, the first and the second charge trapping layers 108 and 110 may have increased charge trapping sites such that a relatively high number of charges may be stored in the first and the second charge trapping layers 108 and 110. When the semiconductor device includes the first and the second charge trapping layers 108 and 110, a difference between a threshold voltage in a programming operation and a threshold voltage in an erasing operation may be increased. Accordingly, operation failures of the semiconductor device may be greatly reduced.

When a semiconductor device only includes a charge trapping layer of nanocrystals, as in the conventional art, a programming/erasing window of the semiconductor device is about 3V. On the other hand, the semiconductor device of the invention may have an increased programming/erasing window of about 6V to about 7V. As the programming/erasing window of the semiconductor device increases, a multi-level operation for storing two or more data into one memory cell may be accomplished by adjusting the number of charges stored in each memory cell of the semiconductor device.

According to the present invention, a semiconductor device may include a gate structure having a first charge trapping layer and a second charge trapping layer. Thus, the number of charges stored in the charge trapping layers may be considerably increased because charge trapping sites of the semiconductor device may be greatly increased. As a result, the semiconductor device may have an improved data retention capability. Further, a diffusion of metal in the second charge trapping layer may be effectively prevented by the first charge trapping layer and/or a dielectric layer so that the semiconductor device may have an enhanced reliability.

According to one aspect of the present invention, there is provided a gate structure including a tunnel insulation layer disposed on a substrate, a first charge trapping layer disposed on the tunnel insulation layer, a second charge trapping layer disposed on the first charge trapping layer, a dielectric layer disposed on the second charge trapping layer, and a conductive layer pattern disposed on the dielectric layer. The first charge trapping layer may have charge trapping sites for storing charges. The second charge trapping layer may include nanocrystals.

In an example embodiment of the present invention, the first charge trapping layer may include a nitride such as silicon nitride.

In other example embodiments, the nanocrystals may include metal nanocrystals or silicon nanocrystals.

In some example embodiments, the second charge trapping layer may include tungsten nitride.

In still other example embodiments, the dielectric layer may include an oxide such as silicon oxide or a metal oxide having a high dielectric constant. Examples of the metal oxide may include aluminum oxide, zirconium oxide, zirconium silicon oxide, hafnium oxide, hafnium silicon oxide, etc. These may be used alone or in a mixture thereof.

According to an aspect of the present invention, there is provided a method of forming a gate structure. In the method of forming the gate structure, a tunnel insulation layer is formed on a substrate, and then a first charge trapping layer is formed on the tunnel insulation layer. The first charge trapping layer may have charge trapping sites for storing charges. A second charge trapping layer is formed on the first charge trapping layer. The second charge trapping layer may include nanocrystals. After a dielectric layer is formed on the second charge trapping layer, a conductive layer is formed on the dielectric layer. The conductive layer is partially etched to form a conductive pattern on the dielectric layer.

According to another aspect of the invention, there is provided a semiconductor device including a substrate having an active region and a field region, a tunnel insulation layer disposed on the active region, a first charge trapping layer disposed on the tunnel insulation layer, a second charge trapping layer disposed on the first charge trapping layer, a dielectric layer disposed on the second charge trapping layer, a conductive layer pattern disposed on the dielectric layer, and impurity regions disposed at portions of the active region adjacent to the conductive layer pattern. The active region may have a protruding pin structure and may extend along a first direction. The first charge trapping layer may include a material including charge trapping sites for storing charges. The second charge trapping layer may include nanocrystals. The conductive layer pattern may have a line shape extending along a second direction substantially perpendicular to the first direction.

According to still another aspect of the invention, there is provided a method of manufacturing a semiconductor device. In the method of manufacturing the semiconductor device, a substrate including an active region and a field region is prepared. The active region may have a protruding pin structure and extends along a first direction. After a tunnel insulation layer is disposed on the active region, a first charge trapping layer is disposed on the tunnel insulation layer. The first charge trapping layer may include a material including charge trapping sites for storing charges. A second charge trapping layer is disposed on the first charge trapping layer. The second charge trapping layer may include nanocrystals. A dielectric layer is disposed on the second charge trapping layer, and then a conductive layer pattern is disposed on the dielectric layer. The conductive layer pattern may have a line shape extending along a second direction substantially perpendicular to the first direction. Impurity regions are disposed at portions of the active region adjacent to the conductive layer pattern.

In the semiconductor device according to example embodiments of the present invention, the gate structure may be disposed on the active region having the pin structure, and the tunnel insulation layer having a three-dimensional structure may be disposed on the active region. Therefore, effective areas of the first and the second charge trapping layers may be considerably increased. Additionally, the number of the nanocrystals in the second charge trapping layer may be greatly increased. Thus, the charge trapping sites in the semiconductor device may be desirably increased so that a difference between a threshold voltage in an erasing operation and a threshold voltage in a programming operation may be greatly increased. Further, the semiconductor device may have an improved reliability because the first charge trapping layer and/or the dielectric layer may effectively prevent metal, which is deposited in the second charge trapping layer, from diffusing into the tunnel insulation layer and/or the conductive layer pattern.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of this invention. Accordingly, all such modifications are intended to be included within the scope of the invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A gate structure comprising:
a tunnel insulation layer disposed on a substrate;
a first charge trapping layer disposed on the tunnel insulation layer, the first charge trapping layer having charge trapping sites for storing charges;
a second charge trapping layer disposed on the first charge trapping layer, the second charge trapping layer including nanocrystals;
a dielectric layer disposed on the second charge trapping layer; and
a conductive layer pattern disposed on the dielectric layer.

2. The gate structure of claim 1, wherein the first charge trapping layer comprises silicon nitride.

3. The gate structure of claim 1, wherein the nanocrystals comprise metal nanocrystals or silicon nanocrystals.

4. The gate structure of claim 1, wherein the second charge trapping layer comprises tungsten nitride.

5. The gate structure of claim 1, wherein the dielectric layer comprises silicon oxide or a metal oxide having a high dielectric constant.

6. The gate structure of claim 5, wherein the metal oxide comprises at least one selected from the group consisting of aluminum oxide, zirconium oxide, zirconium silicon oxide, hafnium oxide and hafnium silicon oxide.

7. A method of forming a gate structure, comprising:
forming a tunnel insulation layer on a substrate;
forming a first charge trapping layer on the tunnel insulation layer, wherein the first charge trapping layer has charge trapping sites for storing charges;
forming a second charge trapping layer on the first charge trapping layer, wherein the second charge trapping layer includes nanocrystals;
forming a dielectric layer on the second charge trapping layer;
forming a conductive layer on the dielectric layer; and
forming a conductive pattern by partially etching the conductive layer.

8. The method of claim 7, wherein the first charge trapping layer is formed using silicon nitride.

9. The method of claim 7, wherein the nanocrystals in the second charge trapping layer comprise metal nanocrystals or silicon nanocrystals.

10. The method of claim 9, wherein forming the second charge trapping layer comprises one or more of a low pressure chemical vapor deposition (LPCVD) process, an ultra-high vacuum chemical vapor deposition (UHCVD) process, and a heat treatment process when the second charge trapping layer includes the metal nanocrystals.

11. The method of claim 7, wherein the second charge trapping layer is formed using tungsten nitride.

12. The method of claim 7, wherein the dielectric layer is formed using silicon oxide or a metal oxide having a high dielectric constant.

13. The method of claim 7, wherein the metal oxide comprises at least one selected from the group consisting of aluminum oxide, zirconium oxide, zirconium silicon oxide, hafnium oxide and hafnium silicon oxide.

14. A semiconductor device comprising:
a substrate including an active region and a field region, the active region having a protruding pin structure and extending along a first direction;
a tunnel insulation layer disposed on the active region;
a first charge trapping layer disposed on the tunnel insulation layer, the first charge trapping layer having charge trapping sites for storing charges;
a second charge trapping layer disposed on the first charge trapping layer, the second charge trapping layer including nanocrystals;
a dielectric layer disposed on the second charge trapping layer;
a conductive layer pattern disposed on the dielectric layer, the conductive layer pattern having a line shape extending along a second direction substantially perpendicular to the first direction; and
impurity regions disposed at portions of the active region adjacent to the conductive layer pattern.

15. The semiconductor device of claim 14, wherein the first charge trapping layer comprises silicon nitride.

16. The semiconductor device of claim 14, wherein the nanocrystals comprise metal nanocrystals or silicon nanocrystals.

17. The semiconductor device of claim 14, wherein the dielectric layer comprises silicon oxide or a metal oxide having a high dielectric constant.

18. A method of manufacturing a semiconductor device, the method comprising:
forming a substrate including an active region and a field region, wherein the active region has a protruding pin structure and extends along a first direction;
forming a tunnel insulation layer on the active region;
forming a first charge trapping layer on the tunnel insulation layer, wherein the first charge trapping layer includes charge trapping sites for storing charges;
forming a second charge trapping layer on the first charge trapping layer, wherein the second charge trapping layer comprises nanocrystals;
forming a dielectric layer on the second charge trapping layer;
forming a conductive layer pattern on the dielectric layer, wherein the conductive layer pattern has a line shape extending along a second direction substantially perpendicular to the first direction; and
forming impurity regions at portions of the active region adjacent to the conductive layer pattern.

19. The method of claim 18, wherein the first charge trapping layer is formed using silicon nitride.

20. The method of claim 18, wherein the nanocrystals in the second charge trapping layer comprise metal nanocrystals or silicon nanocrystals.

21. The method of claim 18, wherein the dielectric layer is formed using silicon oxide or a metal oxide having a high dielectric constant.
